(19) United States
(12) Patent Application Publication
(10) Pub. No.: US 2008/0128017 A1
(43) Pub. Date: Jun. 5, 2008

(54) Solar Energy Collection Systems

(75) Inventor: Graham Paul Ford, Cambridgeshire (GB)

Correspondence Address: TAROLLI, SUNDHEIM, COVELL & TUMMINO L.L.P., 1300 EAST NINTH STREET, SUITE 1700, CLEVEVLAND, OH, 44114, US

(73) Assignee: HELIODYNAMICS LIMITED, Cambridge (GB)

(21) Appl. No.: 11/630,191

(22) PCT Filed: Jun. 16, 2005
(86) PCT No.: PCT/GB05/50090

§ 371 Date: Sep. 7, 2007

(30) Foreign Application Priority Data
Jun. 24, 2004 (GB) 0414183.4
Jun. 24, 2004 (GB) 0414184.2

(51) Int. Cl. H01L 31/042; F24J 2/10; F24J 2/38

(52) U.S. Cl. 136/248; 126/692; 126/600; 29/890.033

(57) ABSTRACT

This invention concerns solar energy collection systems, especially systems that concentrate direct sunlight and then collect the radiant energy. This invention is of particular use for providing heat and power for buildings and industrial processes.

A solar energy collection system comprising: a solar energy receiver; and a solar energy directing system to direct sunlight onto said solar energy receiver; wherein said solar energy directing system comprises a set of mirrors, each mirror having a moveable axis and comprising a plurality of facets, and wherein the facets of each mirror are configured to direct incoming sunlight to focus substantially at said receiver when said mirror axes are directed towards said receiver.

A photovoltaic device comprising a light receiving surface and first and second electrodes for delivering electrical power from the device, the device having at least one high current electrical contact, at least one of said first and second electrodes comprising a plurality of electrically conductive tracks; and wherein said high current electrical contact comprises at least one metallic conductor crossing said plurality of tracks and attached to each track at a respective crossing point, said metallic conductor being configured to permit an increase in separation between said crossing points.

This invention concerns solar energy collection systems, especially systems that concentrate direct sunlight and then collect the radiant energy. This invention is of particular use for providing heat and power for buildings and industrial processes.

This invention further relates to photovoltaic devices and to electrical contacts for such devices as well to methods of fabricating such electrical contacts. The described devices are particularly suitable for use at high energy fluxes such as those encountered in a solar energy concentrator.

Solar energy collection systems have been used as a means to provide either-power or heat without the need to bum fuels or harness terrestrial nuclear power. Until now they have operated by producing heat from the energy of sunlight or they harness that sunlight using the photovoltaic effect to generate power without the need to produce heat as an interim step.

Although considerable progress has been made in reducing the cost and extending the life of such systems, they have not yet reached the point where these systems provide economic returns except in a very few applications.

The reasons for this lack of cost effectiveness depend on the type of system. With photovoltaic systems, the energy required to make the cells, the complexity of the equipment and the rate of production results in a product that is too expensive for the power that can be produced per cell.

For thermal system, the principle issue is the mass of material required to manufacture a given collecting area of solar collector is simply too great to achieve a commercial return. If the masses of the materials are reduced, the result is a system that is too fragile to withstand the environmental forces acting upon it.

Typically, these forces are wind gusts, impacts from falling objects caught up in high winds, lightning, hail, corrosion and degradation from ultraviolet rays.

The problems of cost effectiveness could, in principle, be addressed if the power output of each photovoltaic cell could be raised by illuminating the cell with concentrated sunlight many times greater than the intensity experienced on the earth's surface and collecting the heat absorbed by the cells, using a solar collection system that was lighter and required less quantity of ordinary engineering materials to achieve the functions of concentration and collection over a given area while offering resilience to the environmental forces. In addition, the efficiency of collection should remain high so that the area required for a given energy collection is not substantially increased compared to current systems.

Background prior art can be found in US 2004/0074490 and W02004/029521 as well as on the websites of Solar Focus, Inc (see also U.S. Pat. No. 6,276,359), Solarmundo and Power-Spar.

Aspects of the invention aim to address the above problems and to provide a solar collection system that can be used for either or both of heat production and photovoltaic power production.

Solar Energy Collection

According to a first aspect of the present invention there is therefore provided a solar energy collection system comprising: a solar energy receiver; and a solar energy directing system to direct sunlight onto said solar energy receiver; wherein said solar energy directing system comprises a set of mirrors, each mirror having a moveable axis and comprising a plurality of facets, and wherein the facets of each mirror are configured to direct incoming sunlight to focus substantially at said receiver when said mirror axes are directed towards said receiver.

In a related aspect the invention provides a solar energy collection system comprising: a solar energy receiver; and a solar energy directing system to direct sunlight onto said solar energy receiver; wherein said solar energy directing system comprises a set of mirror assemblies, each mirror assembly having a moveable axis and comprising a plurality of mirror elements, and wherein the elements of each mirror are configured such that when each mirror axis is directed substantially towards said receiver there is a reference direction from which incoming substantially parallel light is substantially focussed onto said receiver.

The conventional way of using a mirror is to angle it so that its (perpendicular) axis bisects the angle between an incident and a reflected ray. However investigations have shown that in a solar energy collection system with distributed mirrors, as the angle of the sun changes so the changing tilt of the mirrors (by half the angle of the sun's motion) results in two types of distortion, described further later. The effect of this distortion is to move and spread the focal region. However the applicant's have found by directing the axis of each mirror substantially towards the solar energy receiver this distortion (and resulting loss of energy efficiency) may be substantially reduced. However a conventional mirror cannot be used in this matter as incident and reflected rays have equal angles to a normal to the mirror surface (which in a conventional mirror defines a mirror axis). The applicant's have, however, further recognised that by fabricating a mirror from a plurality of mirror elements or facets, which for ease and cheapness of fabrication are preferably planar, incoming off-axis light can effectively be focussed so that it is on-axis. This allows a mirror construction in which the facets of the mirror (that is of any one mirror of the system) are at substantially equal distances from the solar energy receiver, at least when the system is configured for focussing light incoming from a reference direction. This “substantially equal distance” criterion effectively optimises the focus of the system so that, for example, as the mirrors tilt to adjust for light coming from a direction other than this reference direction distortion (i.e. de-focussing) is substantially reduced or minimised. Thus the mirror axis may be defined such that points on the axis meet this “substantially equal distance” criterion. Additionally or alternatively the axis may be substantially perpendicular to a plane defined by the facets, or more particularly supports of the facets. The mirror axis may therefore be considered to be a form of mechanical axis, preferably passing substantially through a mechanical centre of the mirror and substantially perpendicular to the supports of the facets.

The mirrors are preferably configured to tilt, in particular to rotate about a longitudinal axis, to accommodate changes in the apparent height of the sun during the day, autumn. The reference direction preferably therefore corresponds to the mid-point of travel of the sun in a vertical direction, in embodiments which rotate the mirrors about a longitudinal access, seen in a direction perpendicular to this longitudinal access. In this embodiment as the sun rises and falls the mirrors are rotated to maintain an “image” on the solar energy receiver (although there will generally be some left-right motion of this image). In embodiments the mirrors are tilted (or rotated) at half the rate of the sun's apparent motion and, unlike conventional systems, all the mirrors are rotated at substantially the same rate. The aforementioned configuration of the mirror system reduces or minimises distortion/de-focussing during such mirror rotation.

As previously mentioned, preferably all the facets of a mirror are at substantially the same distance from the solar energy receiver. In other words, preferably the (moveable) mirror axis is that direction (towards the receiver) about which the facets are disposed at substantially equal distances to the receiver. In practice this “equal distance” requirement may effectively be satisfied by positioning the facets of a mirror in substantially the same plane since the difference between a plane and an arc in a practical system is generally only a few millimetres and of little or no great significance. Thus preferably, for convenience and ease of fabrication, the facets of a mirror are mounted in a common plane, for example on a supporting cradle (for example, the centres or supports of the facets defining a common plane). In such a configuration the axis of the mirror is substantially perpendicular to this plane.

In the above described arrangement with substantially planar mirrors a preferred embodiment has longitudinally extending mirrors which, similarly to a cylindrical mirror, focus in substantially only one direction, that is to provide a line or stripe focus at the receiver. In such an arrangement the receiver is parallel to the longitudinal mirror axes and the mirrors are mounted for rotation about a respective axes which are also parallel to the receiver. Any conventional mechanical mounting means can conveniently be employed; a simple drive arrangement may be used since preferably all mirrors are rotated at the same rate, for example comprising a set of equal length cranks linked to a common arm.

In another aspect the invention provides a solar energy directing system comprising: a plurality of mirror assemblies, each having mounted thereon a plurality of mirror elements, said mirror elements of a mirror assembly having a fixed mutual position and orientation; and a plurality of mirror assembly supports each configured to provide a respective mirror assembly with an axis of rotation about a longitudinal direction, said axes of rotation being substantially mutually parallel, and wherein said mirror assemblies are configured to bring incoming parallel light to a stripe focus substantially parallel to said longitudinal direction.

In a related aspect the invention provides a solar energy directing system comprising: a plurality of mirror assemblies, each having mounted thereon a plurality of mirror elements, said mirror elements of a mirror assembly having a fixed mutual position and orientation; and a plurality of mirror assembly supports each configured to provide a respective mirror assembly with an axis of rotation about a longitudinal direction, said axes of rotation being substantially mutually parallel; and wherein said mirror assemblies are configured for rotation in synchrony each at substantially the same rate.

According to a further aspect of the present invention there is provided a solar energy collection system comprising: a solar energy receiver; and a solar energy directing system to direct sunlight onto said solar energy receiver; wherein said solar energy directing system comprises a set of Fresnel mirrors, each comprising a plurality of mirror facets, each positioned at an angle with respect to a reference direction such that incoming light from said reference direction is reflected towards said solar energy receiver; and wherein at least some of said Fresnel mirrors are configured as off-axis mirrors such that incoming parallel off-axis rays are focussed on-axis.

Embodiments of the above described system enable the fabrication of a relatively inexpensive and easy to assemble structure which is relatively stiff (has low bending moments) to better withstand wind loads. Furthermore in embodiments the physical height of the solar energy directing system may be relatively low, thus providing reduced wind resistance.

Preferably each mirror facet has a substantially planar reflecting surface, preferably each mirror facet being positioned such that the incoming light from the reference direction is directed towards the solar energy receiver. As well as flat reflectors being relatively inexpensive, use of a flat reflecting surface facilitates even illumination of an energy collecting portion of the solar energy receiver as compared, for example, to a curved surface which would tend to bring light to a focus at a point on the receiver. As the sun subtends a small angle (approximately half a degree) and light from the sun is effectively parallel the size and orientation of a facet can define a substantially rectangular (or more properly trapezoidal) distribution of light intensity on the receiver. Preferably therefore a mirror facet has a dimension such that reflected incoming light extends substantially uniformly over no more than an energy collecting portion of the solar energy receiver, at least for incoming light along the reference direction.

Preferably the mirrors are movable, and more particularly rotatable about an axis, as discussed below a longitudinal axis. An actuator may be provided to rotate the mirrors in synchronison, all by the same angle; the rotation of the set of mirrors is preferably coordinated so that together they compensate for motion of the sun. To reduce power consumption a suitable actuator may comprise a ratchet and pawl drive.

Thus in another aspect the invention provides an actuator comprising a wheel, preferably toothed, and a set of pawls positioned around the wheel each acting to turn the wheel through a portion of a complete rotation. The pawls may be operated in sequence to push the wheel around forwards or backwards; this rotary motion may be converted to a linear motion by rack and pinion arrangement. This may then be employed to drive a mirror.

In preferred embodiments each mirror extends longitudinally such that sunlight is directed in to a line or stripe at the solar energy receiver, the receiver extending longitudinally along a direction of this line. A mirror may have an aspect ratio of 5:1, 10:1, 20:1, 30:1, 40:1, 50:1 or greater. A mirror is preferably rotatable about its longitudinal direction. At an equinox (and in the tropics near the equator) the sun has a substantially constant angle to the above mentioned reference direction throughout a day and thus the angle of the mirrors need not be varied. However in embodiments no provision is made for rotation perpendicular to the longitudinal direction so that the line into which the sunlight is directed will move across the energy collecting portion of the solar energy receiver as the day passes and will normally overlap rather than be co-incident with this energy collecting portion. However during the summer or winter the altitudinal angle of the sun will change as the day passes and the mirrors are preferably therefore rotated about their longitudinal axis to compensate for this.

In preferred embodiments a mirror can be rotated to substantially invert the reflecting face (which normally points upwards) so that this points downwards, presenting a rear face of the mirror to the sky. This rear face is preferably provided with a shield such as a mesh to provide weather protection, in particular from hail. Inversion of the mirror may be performed in response to a signal from a sensor which may comprise, for example, a microphone or accelerometer.

Thus in another aspect there is provided a solar energy collection system comprising a set of mirrors and associated shields, and a weather, in particular hail sensor, the system being configured to respond to a signal from the sensor indicating inclement weather to deploy the shields to protect the mirrors. In embodiments a shield is provided at the back of each mirror and in response to the signal from the sensor the mirrors are moved so as to present the shield to the weather, such as hail stones, to protect die reflecting surfaces of the mirrors.

In preferred embodiments of the system the set of mirrors comprises between two and ten mirrors, preferably between four and six or eight mirrors. In embodiments each mirror may be provided with between two and twenty facets, preferably two to ten facets, more preferably four to six or eight facets. The mirrors may for convenience be positioned in substantially a common plane such as the ground or the roof of a building.

The reference direction is defined by preferably substantially equal to an installation attitude for the system; this may be adjustable. In preferred embodiments the solar energy receiver is mounted so that it points generally downwards to the mirrors as in this way it is less prone becoming dirty.

The system may be employed for supplying heat, or electrical power, or both. When used to supply heat because heat losses are roughly constant per unit length (of a longitudinal configuration) at a given temperature of operation, as a proportion these losses can be reduced by increasing the effective solar energy collecting area per unit length.

Thus in another aspect the invention provides a solar energy collection system comprising: a solar energy receiver configured for supplying for use both heat and electrical power; and a solar energy directing system to direct sunlight onto said solar energy receiver; wherein said solar energy directing system comprises a set of mirrors, each positioned at an angle with respect to a (predetermined) reference direction such that incoming light from said reference direction is reflected towards said solar energy receiver; wherein each said mirror extends longitudinally such that said sunlight is directed into a stripe at said solar energy receiver, and wherein said receiver extends longitudinally along a direction of said stripe; said set of mirrors taken as a whole providing a reflecting surface with an aspect ratio of greater than 5:1.

In determining the aspect ratio the reflecting portion of the mirrors (rather than the space in between the mirrors) is measured. In preferred embodiments the reflecting surfaces extend longitudinally at least 10 or 12 metres and laterally at least 1 metre, more preferably 1.5 metres, 2 metres or more.

Choice of a suitable aspect ratio facilitates operation of a system configured to supply at least heat, for example using a heat transfer fluid such as water (or steam). In embodiments this fluid is heated to close to its boiling point as determined for the fluid under atmospheric pressure, for example greater than 90° C., more preferably 95° C. for water. This fluid is then particularly suitable for use in an air conditioning system, for example of the type which relies upon latent heat of evaporation to provide cooling.

Thus in another aspect there is provided a solar energy collection system comprising: a solar energy receiver configured for supplying for use both heat and electrical power; and a solar energy directing system to direct sunlight onto said solar energy receiver; and wherein said receiver includes a photovoltaic device and conductors for a heat transfer fluid, and wherein said energy collection system is configured such that in operation said heat transfer fluid is heated to close to a boiling point of the fluid as determined for the fluid under atmospheric pressure.

In some potential applications more than half a building's power consumption is used for air conditioning and lighting. Thus a solar energy collecting system such as that described above can be mounted on a roof so as to provide diffuse daylight through gaps between the mirrors for illuminating the building whilst substantially reducing or eliminating unwanted direct sunlight.

Thus the invention further provides a building having a solar energy collection system including a solar energy receiver configured for supplying for use both heat and electrical power; wherein the system is mounted on a roof of the building such that at least a portion of the building is illuminated by indirect sunlight passing between mirrors of said set of mirrors.

Other aspects of the invention, which are described in more detail below, are as follows:

An energy collection system comprising:

a substantially flat light energy absorbing surface, and

at least one substantially flat light reflecting surface cooperating with the absorbing surface to reflect light onto the absorbing surface, characterised in that the absorbing surface and the reflecting surface are located so that the normal of the reflecting surface intersects the principle axis of the absorbing surface when the sun is at an altitude equal to halfway of its maximum altitudinal transverse.

A light reflecting element comprising:

at least one substantially flat light reflecting surface, and

a holder carrying the reflecting surface, the holder being rotatable around at least one axis parallel to the reflecting surface.

A light reflecting element comprising:

a holder carrying a plurality of reflecting surfaces, the bolder being rotatable around at least one axis parallel to the reflecting surface, and

a plurality of longitudinal substantially flat light reflecting surfaces, wherein longitudinal axes of symmetry of the reflecting surfaces carried by the holder are in a single plane.

A drive mechanism for a plurality of holders carrying reflecting surfaces, comprising:

a central driving wheel, and

a plurality of transmission elements connecting to the central driving wheel, each of the transmission elements individually coupled to one of the holders.

A method for driving a plurality of holders carrying reflecting surfaces.

An energy collection system comprising a combination of at least one thermal energy collector and at least one photovoltaic energy collector.

An assembly of a plurality of photoelectric energy collectors, the connectors of which collectors are braided.

A method for forming a plurality of separate solder spots.

A grid of photoelectric energy collectors having a spacing between the individual collectors of 0.8 to 1.4 mm.

Photovoltaic Devices

A conventional silicon photovoltaic device typically comprises a slab of silicon within which is formed a semi- conductor junction. A conductive back plane is provided, typically of aluminium. On the light receiving surface an electrode comprising a plurality of electrically conductive tracks (sometimes known as tabbing strips) is used so that this surface is not obscured. These conductive tracks may comprise, for example, a silver-loaded glass frit. Often a limited a number of similar conductive tracks is provided on the aluminium back plane for increased electrical conductivity. The semiconductor may comprise amorphous, microcrystalline, polycrystalline (millimetre sized crystals) or monocrystalline silicon and/or some other material such as gallium arsenide.

A solar concentrator is a solar energy collection system which provides sunlight to a receiver at a flux which is greater than that falling on the collection system. The solar flux at the Earth's surface at 25° C. through a thickness of one and a half atmospheres (an incidence angle of 45°) is conventionally taken to be 1 KW/m²; here we are particularly concerned with systems which provide 2:1 concentration, more particularly systems which provide a concentration of 5 or more times, for example operating at 7 or 8 KW/m². At such fluxes a silicon-based photovoltaic device will generate around 0.4 volts at up to 30 amps and it will therefore be appreciated that it is very important to keep the resistance of connections to the device low so as not to lose significant amounts of power in the connections to the device. This problem is exacerbated where photovoltaic devices of relatively large area are employed, for example of more than 10 cm on a side.

Another problem associated with the use of photovoltaic devices in solar concentrators relates to the heating of the device which takes place. This causes thermal expansion of the silicon which can disrupt electrical connections, reducing efficiency and potentially destroying the device.

A structure for very high power photovoltaic devices, operating at up to 100 KW/m², is known from WO02/15282, this employing a series of laser-cut trenches in the surface of the device filled with copper to conduct electrical power from the device. However such an arrangement is very expensive to manufacture and requires a specialised plant.

According to an aspect of the present invention there is therefore provided a photovoltaic device comprising a light receiving surface and first and second electrodes for delivering electrical power from the device, the device having at least one high current electrical contact, at least one of said first and second electrodes comprising a plurality of electrically conductive tracks; and wherein said high current electrical contact comprises at least one metallic conductor crossing said plurality of tracks and attached to each track at a respective crossing point, said metallic conductor being configured to permit an increase in separation between said crossing points.

In one embodiment the metallic conductor comprises pre-compressed braid, preferably copper braid. This is preferably also looped between the crossing points, and in this way thermal expansion of the device can take place without undue disruption of a connection of the metallic conductor to one of the electrically conductive tracks.

Preferably the conductor is soldered to each track using a solder which matches the material of the track, for example silver-loaded solder for silver-loaded tracks. In a fabrication process for attaching the conductor described further below the tracks are pre-loaded with spots of solder at the crossing points and then this solder is then melted into the braid, for example using electrical heating.

In embodiments of the invention there is no need for the tracks to be embedded within channels cut into the surface of the device and instead the tracks may, as in lower power devices, simply overlay a surface of the device (which may be an internal surface).

Preferably a plurality of high current electrical contacts is provided for at least the upper electrode (that on the light receiving surface) for increased electrical conduction; these are preferably spaced at intervals across the surface of the device. In preferred embodiments a similar high current conductor is also provided for the tracks on the back plane of the device.

In a conventional photovoltaic device the conductive tracks or tabbing strips are spaced relatively wide apart. However at high incident solar fluxes and consequent high currents the voltage drop across the semiconductor from a position between two tracks to one or other of the tracks becomes a significant source of potential power loss. It can be shown theoretically that this voltage drop is proportional to the resistivity of the semiconductor material, the concentration factor (for example 2 for 2 times solar concentration) and to the square of the separation between adjacent electrically conductive tracks. In preferred embodiments, therefore, this distance is reduced (scaled down) by the inverse square root of the concentration factor—for example halved for a concentration factor of four.

Thus in another aspect the invention provides a photovoltaic device with at least one electrode comprising a plurality of electrically conductive tracks, for use in a solar concentrator with a pre-determined concentration factor, in which the separation of the tracks is substantially equal to or less than a value determined according to a square root of the concentration factor.

In preferred embodiments, suitable for use with the systems described later, the conductive tracks have a spacing of less than 2 mm, less than 1.5 mm or less than 1 mm.

Thus in another aspect the invention provides a photovoltaic device comprising a light receiving surface and first and second electrodes for delivering electrical power from the device, at least one of said first and second electrodes comprising a plurality of electrically conductive tracks and wherein said conductive tracks have a spacing of less than 2 mm, more preferably less than 1.5 mm or 1 mm.

The invention further provides a solar energy collection system including a photovoltaic device, means to concentrate collected solar energy onto said device, and cooling means for said device, said photovoltaic device comprising a light receiving surface and first second electrodes for delivering electrical power from the device, at least one of said first and second electrodes comprising a plurality of electrically conductive tracks, and wherein said tracks relay a surface of said device.

In preferred arrangements the above described photovoltaic devices may be utilised in conjunction with a cooling system, for example a plurality of fluid channels for carrying a heat transfer fluid. This cooling system is preferably configured to supply heat for delivery for use in conjunction with or separately from electrical power from the photovoltaic device.

The invention further provides a process for attaching an electrical contact to a photovoltaic device, the photovoltaic comprising a light receiving surface and first and second electrodes for delivering electrical power from the device, at least one of said first and second electrodes comprising a plurality of electrically conductive tracks, the method comprising: applying solder to said plurality of tracks at points where said contact is to be attached; placing said electrical contact adjacent one or more of said attachment points; and heating said one or more attachment points to melt said solder and attach said contact at said attachment points.

Preferably the electrical contact comprises a braid such a metal, in particular copper braid. However such a material is a good wick so that it is advantageous to pre-apply solder to the conductive tracks where the braid is to be attached. Soldering is particularly advantageous: mere physical contact tends to result in poor electrical conductivity, as does aluminium- or silver-loaded epoxy adhesive, and welding tends to damage the tracks and underlying material.

In particularly preferred embodiments of the process a carbon electrode such as a carbon pencil encased within a copper tube, is placed on each attachment point in turn (or in parallel on a series of attachment points) and a current is passed through the carbon electrode, through the contact to be attached, and back via a return path to heat the carbon so that this locally melts the solder. Optionally solder may be pre-applied to the braid in a tinning process, but this has been found unnecessary in practice.

In preferred embodiments of the process the initial application of the solder to the tracks, and the heating process to melt the solder to attach the contact is performed sufficiently quickly that the electrically conductive tracks suffer no significant damage.

These and other aspects of the invention will now be further described, by way of example only, with reference to the accompanying figures in which:

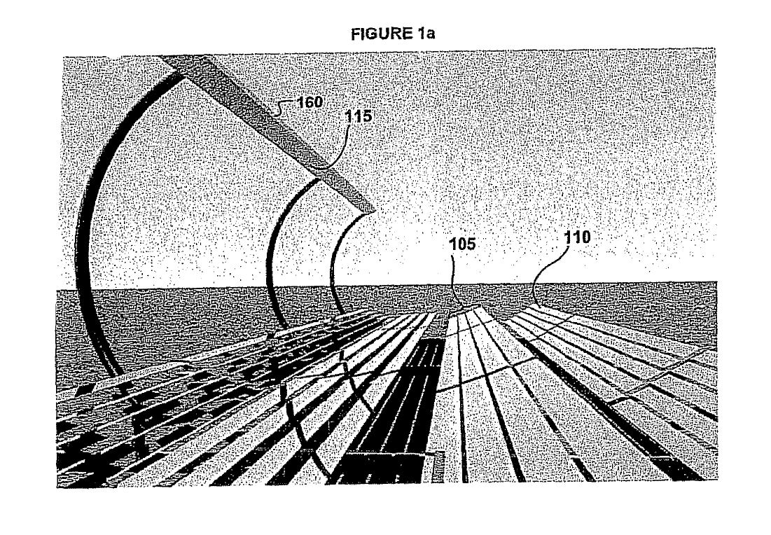

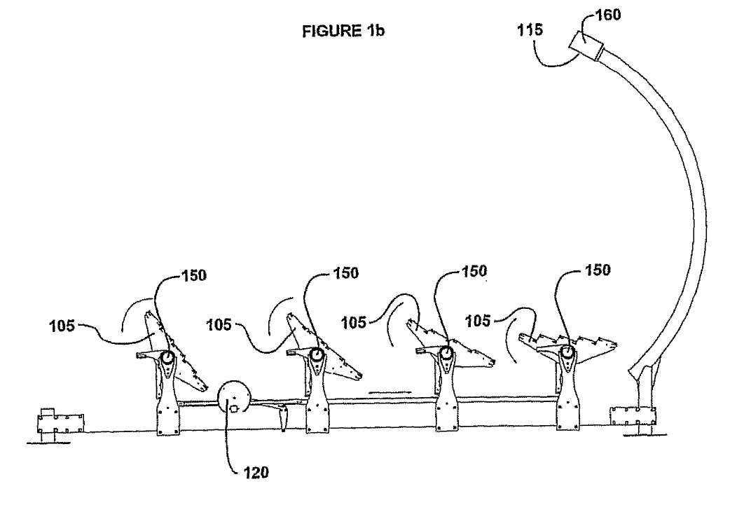

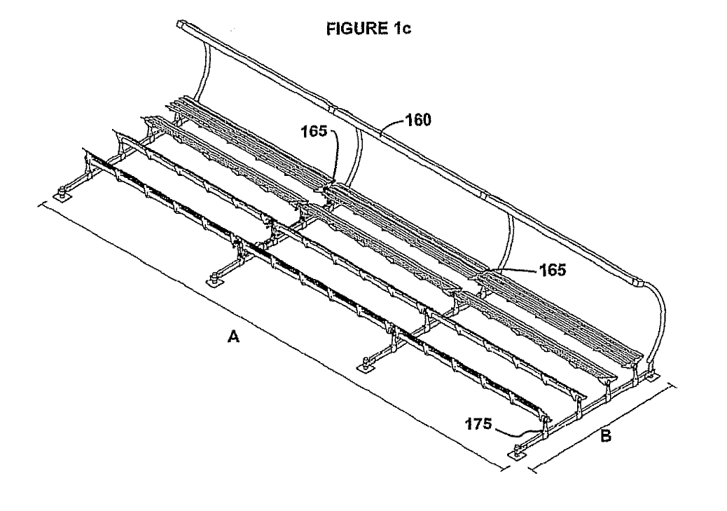

FIGS. 1a to 1d show, respectively, a perspective view of a system of distributed mirrors embodying an aspect of the present invention, a side view of the system of FIG. 1a, a second perspective view of the system of FIG. 1a, and a perspective view of the system of FIG. 1a mounted on a roof;

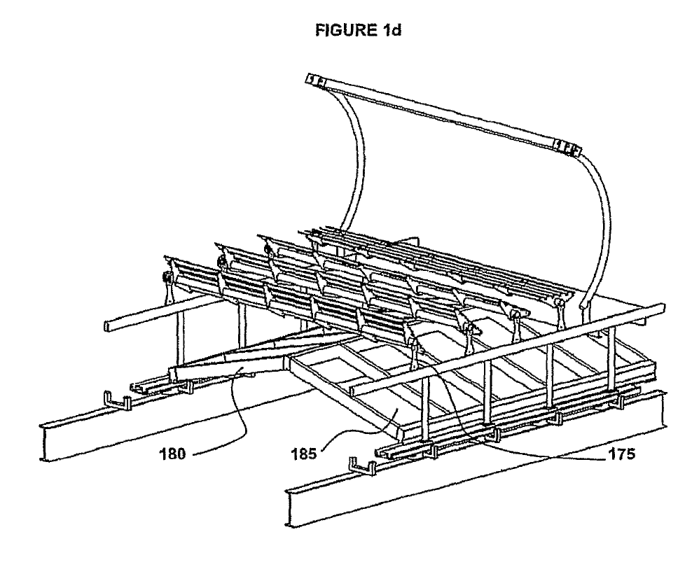

FIGS. 2a to 2d show, respectively, a sub-optimal system of reflectors configured for a tropical location with sunlight striking the reflectors vertically, the system of FIG. 2a when the solar altitude is 60 degrees lower, an improved configuration with geometry is suitable for a tropical location with sunlight striking the reflectors vertically, and the improved system of FIG. 2c with the sun 60 degrees lower;

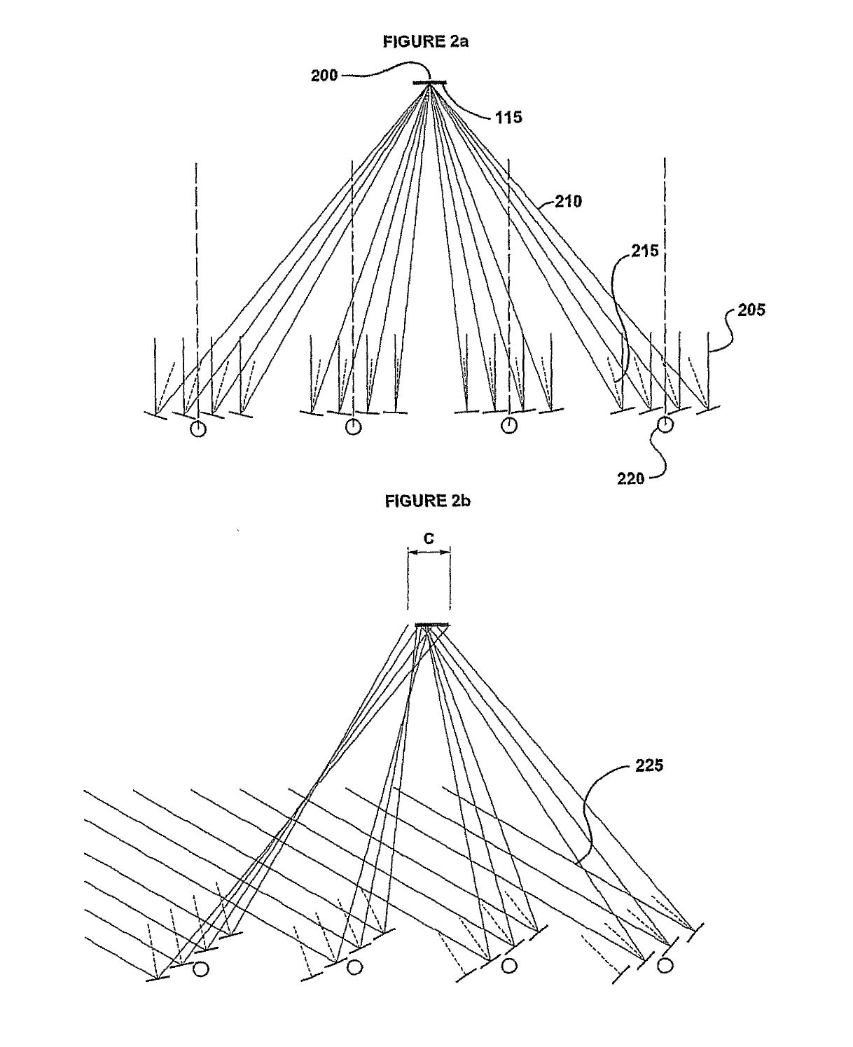

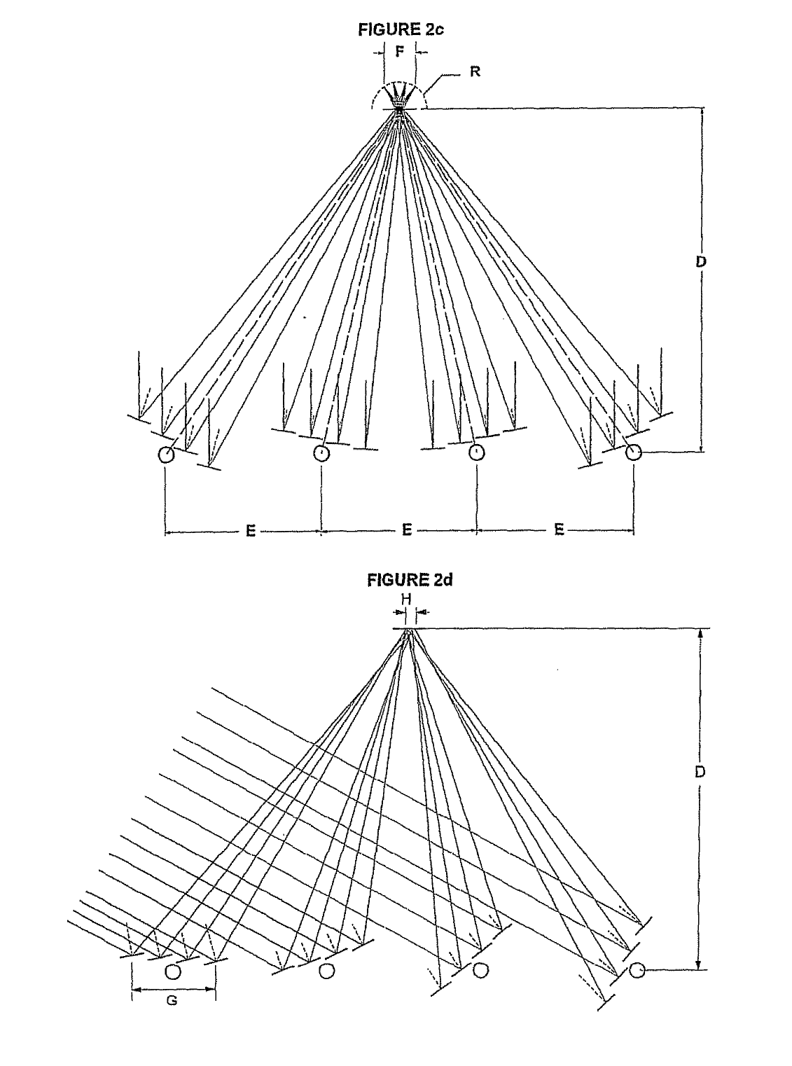

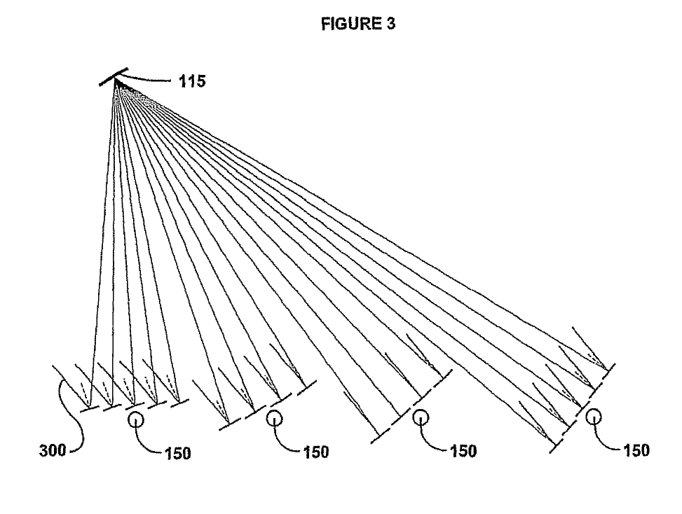

FIG. 3 shows a system of concentrators similar to the system of FIGS. 2c and 2d but configured for a mid-latitude location;

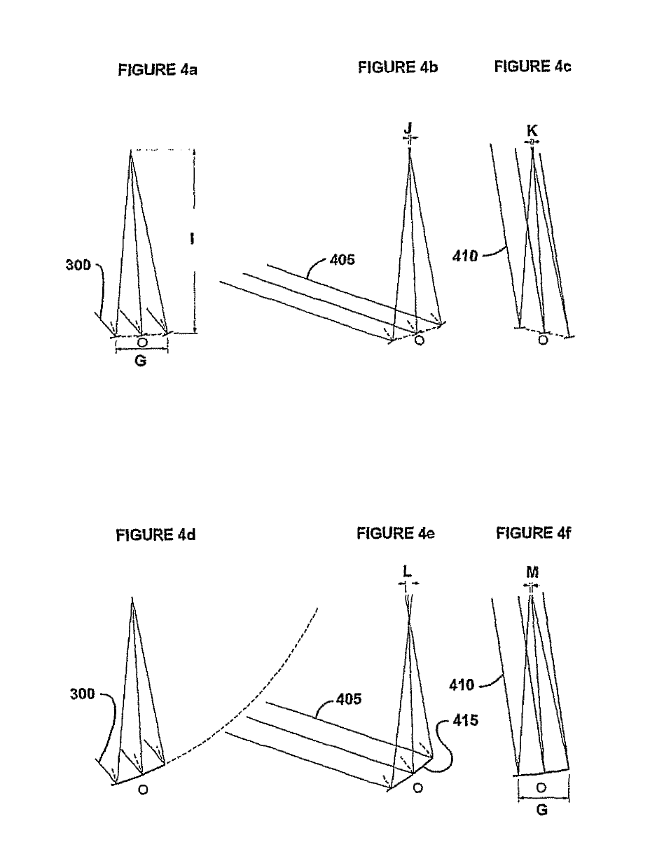

FIGS. 4a to 4f show, respectively, outer and centre facets of the mirror beneath the focal stripe shown in FIG. 3 with light is striking the mirror from a reference direction, the arrangement of FIG. 4a with light striking the mirror from much lower in the sky, the arrangement of FIG. 4a with light striking the mirror from higher in the sky, a parabolic mirror with an offset vertex with light is striking the mirror from a reference direction, the parabolic mirror of FIG. 4c with light striking the mirror from much lower in the sky, and the parabolic mirror of FIG. 4c with light striking the mirror from higher in the sky;

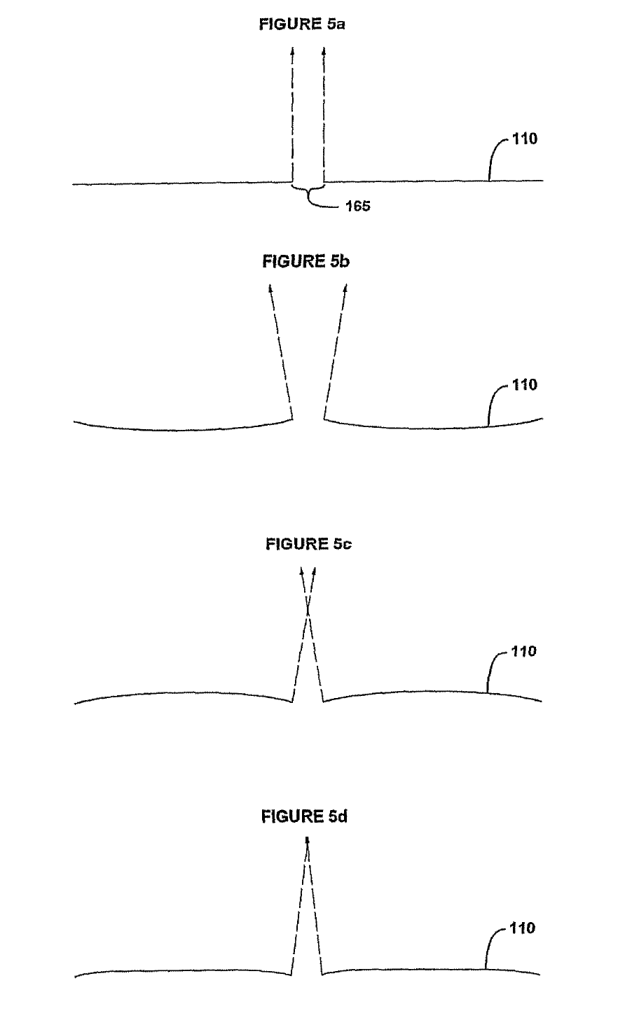

FIGS. 5a to 5d show, respectively, two reflective laminated mirror facets with a gap for a bearing, the mirror facets of FIG. 5a showing deflection due to self-loading, the mirror facets of FIG. 5a preformed with a slight curvature, and the preformed mirror facets of FIG. 5c when loaded with their own weight;

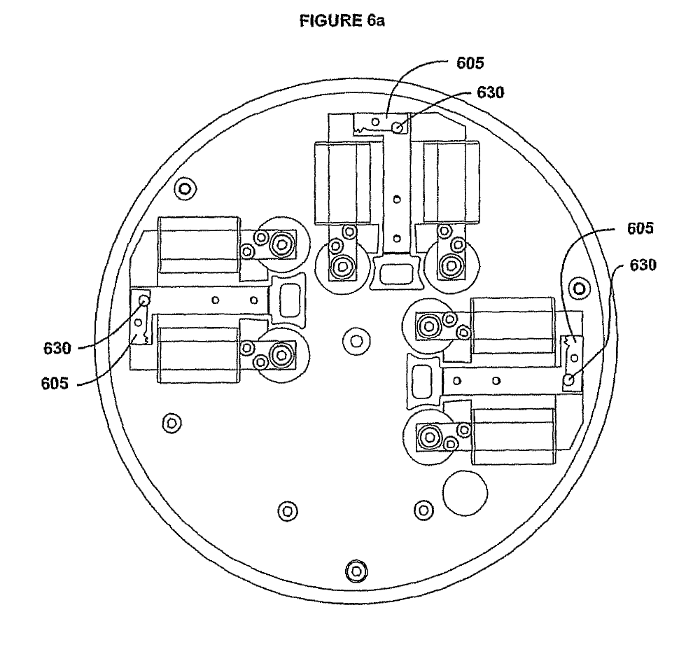

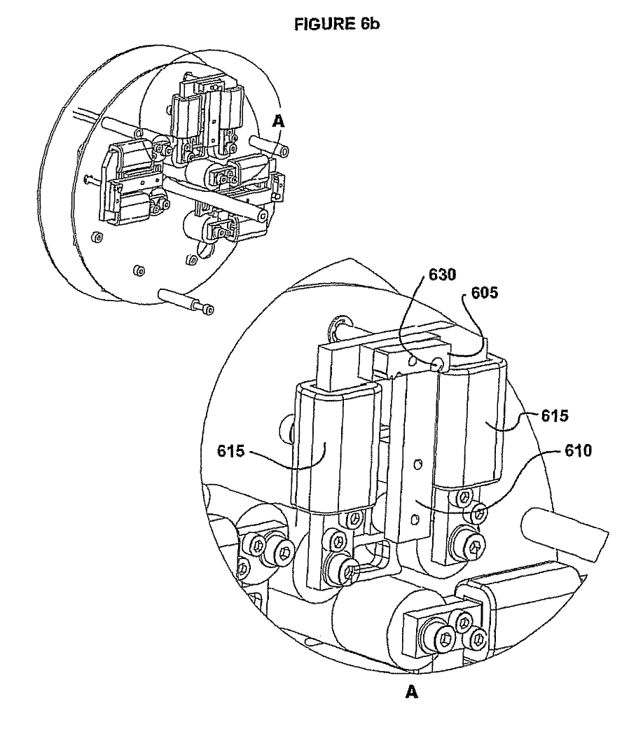

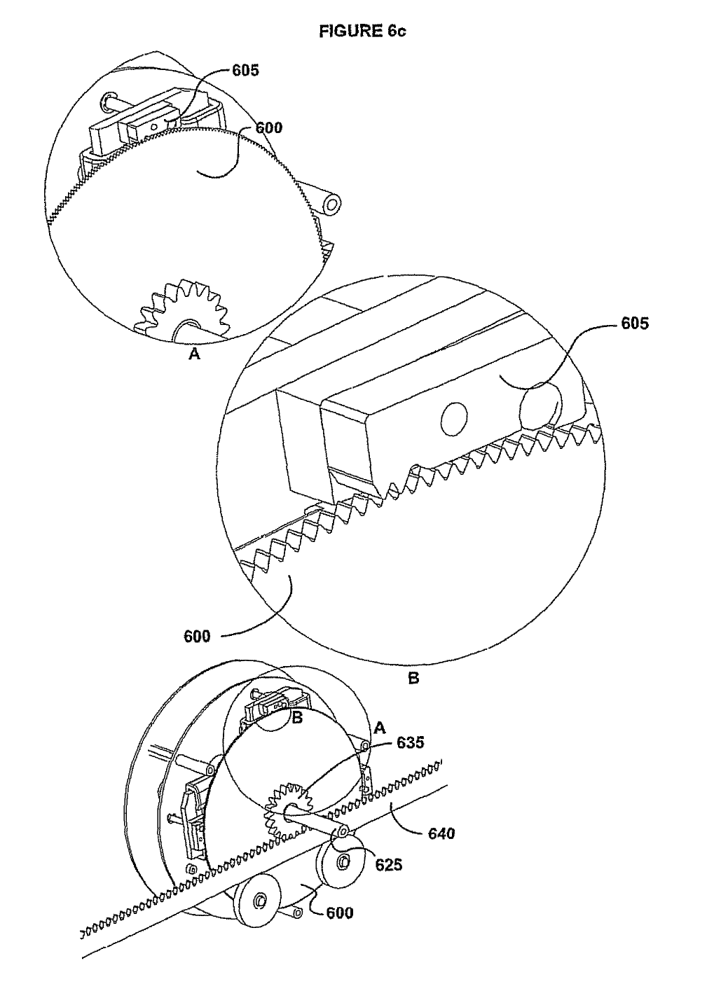

FIGS. 6a to 6c show, respectively, an internal view of an actuator for driving a drawbar for tilting the mirrors in the system of FIG. 1, an isometric view of an actuator of FIG. 6a showing a pawl, and the pawl of FIG. 6b engaging a gear that drives a rack-and-pinion to move the drawbar;

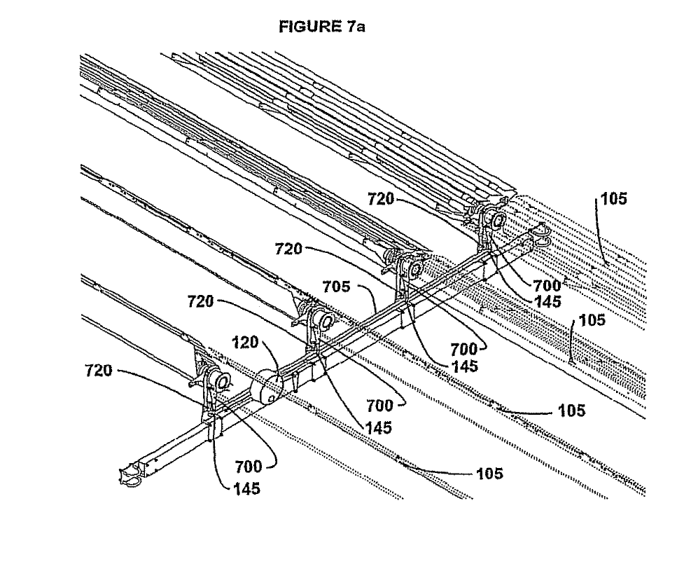

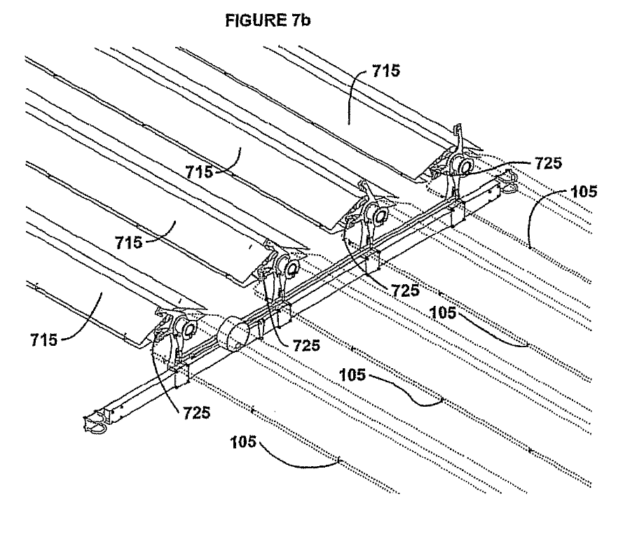

FIGS. 7a and 7b show, respectively, details of an actuator and drawbar in the system of FIG. 1, and the system of FIG. 1 with the mirrors in an inverted position for protection;

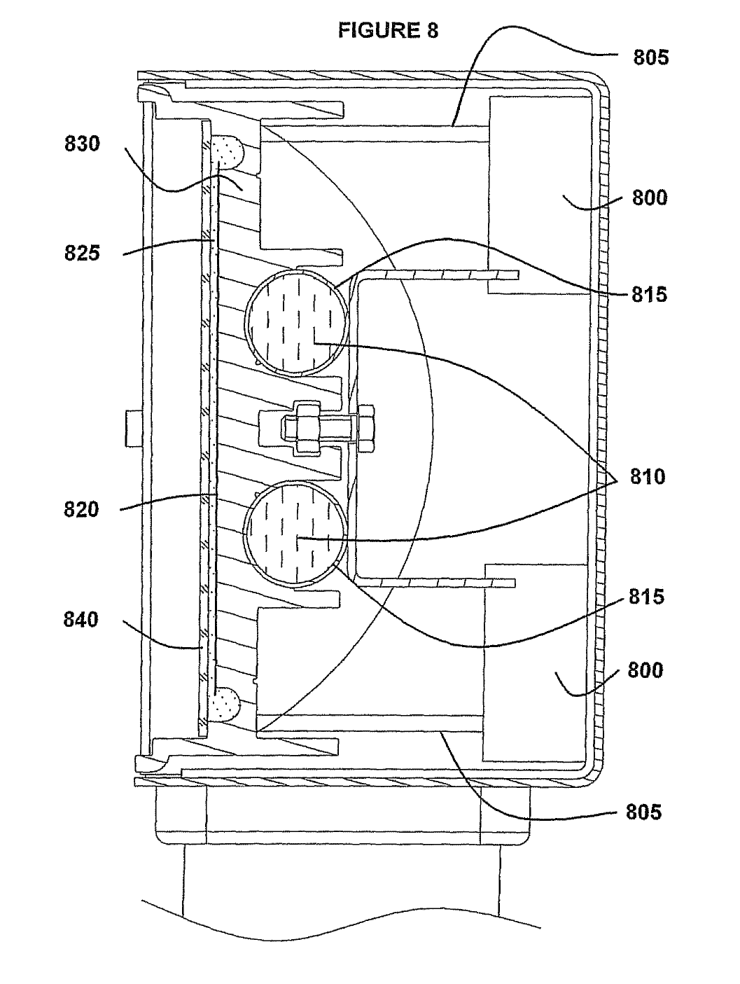

FIG. 8 shows a cross sectional view trough a solar energy receiver for the system of FIG. 1;

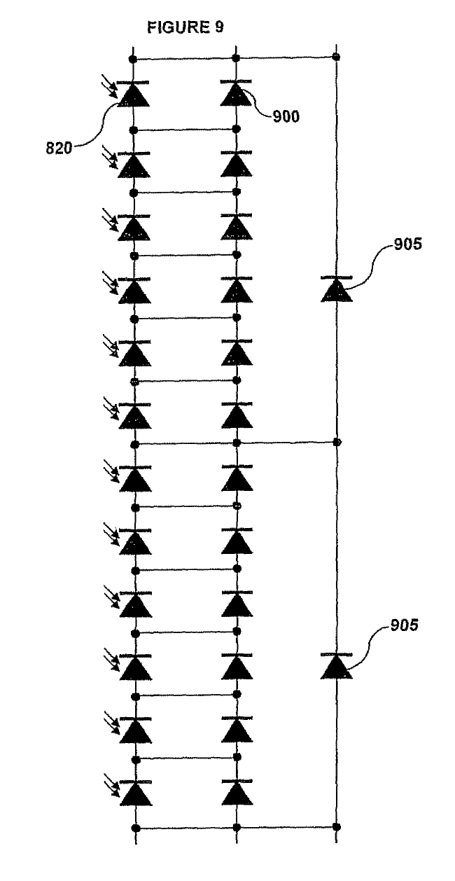

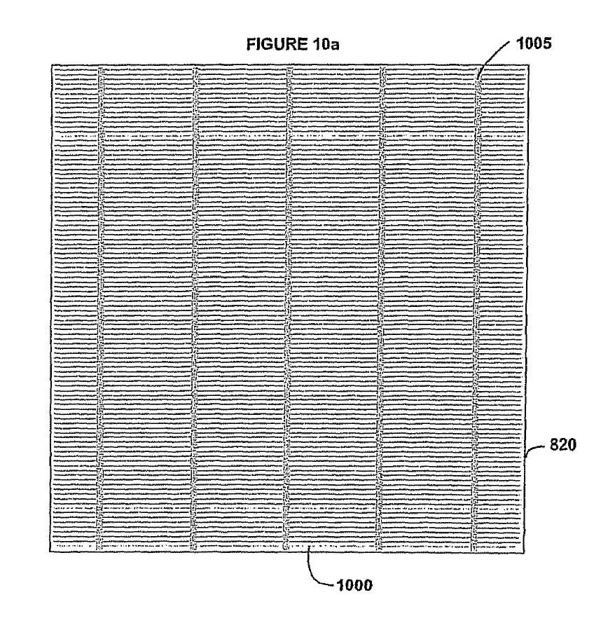

FIG. 9 shows a circuit diagram of photovoltaic cells in the receiver of FIG. 8; and

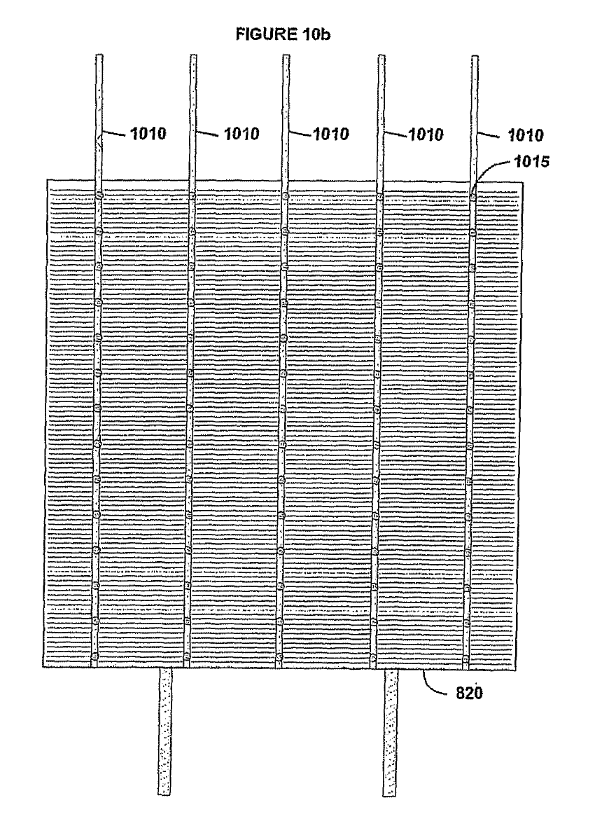

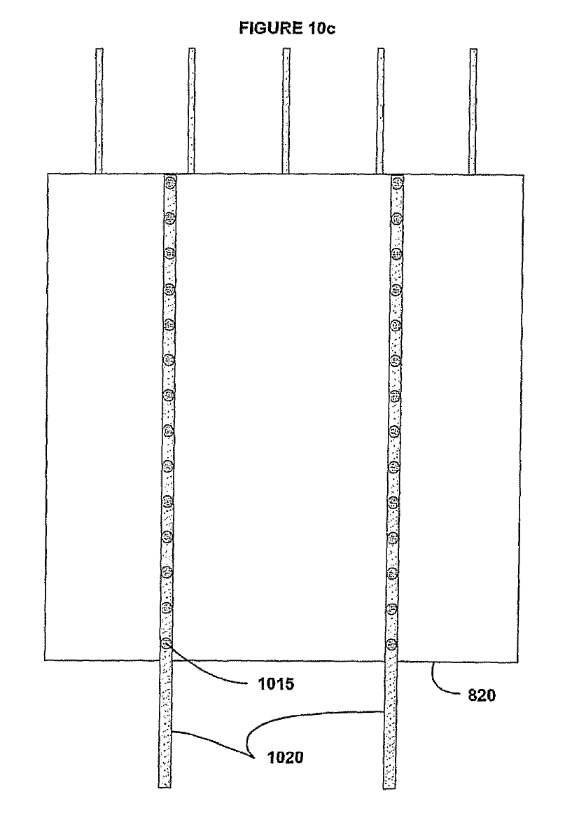

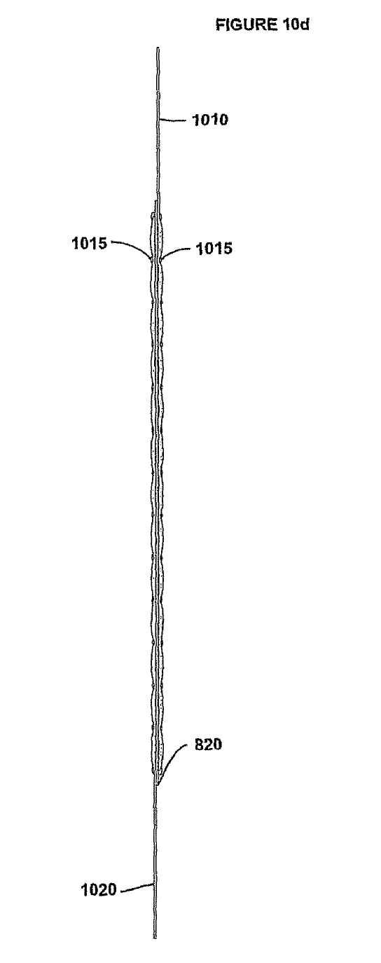

FIGS. 10a to 10d show, respectively, a front illuminated surface of a photovoltaic cell, the front surface of the cell of FIG. 10a provided with braided electrical conductors, a rear surface of the cell of FIG. 10a provided with braided electrical conductors, and a side view of the cell of FIG. 10a provided with front and rear surface braided electrical conductors.

Broadly speaking we will describe a fixed receiver which is much longer than it is wide. Preferably it has a light absorbing face whose geometric normal is oriented towards a reflector means. Preferably it also has an electrically insulated but thermally conductive element enabling the passage of heat from the absorbing face to one or more tubular passages with axes parallel to the fixed principle axis of the receiver through which fluid may be passed for the collection and transference of absorbed thermal energy from the receiver to any device which requires thermal energy for its functioning, while also permitting the optional adherence of photovoltaic cells to the light absorbing face of the thermally conductive element without electrical short-circuiting the cells;

Preferably it has a reflector means for concentrating direct sunlight and directing the reflected beams onto the receiver consisting of a number of rotatable reflector cradles (rotating about fixed axes parallel to the principle axis of the receiver), each cradle rigidly locating more than one strips of flat solar-reflective lamination; each strip having a width approximately equal to (or narrower than) the width of the absorbing face of the receiver. The axes of symmetry of each strip on any cradle lie on a plane, the principle cradle plane, whose normal intersects a line close to or coincident with the principle axis of the receiver absorbing face when reflecting sunlight onto the receiver when the sun is at an altitude equal to a design altitude measured relative to the plane in which all of the axes of rotation of the cradles lie (the ‘design sun angle’) and where the focal line of the reflective lamination strips for a given cradle, the receiver principle axis, the centreline of the principle cradle plane, the normal to the principle cradle plane passing through this centreline and the axis of rotation of the cradle pivot all lie on a common plane when the cradle is focusing on the receiver sun light from sun altitude equal to its ‘design sun angle’, the design sun angle being selected to optimise the year round light collecting performance of the system;

Preferably it also has an electromagetically operated actuator for rotating the reflector cradles consisting of three bistable electromagnetic actuators operating such that each actuator in turn drives and then locks a toothed wheel with one or more engaging teeth, the wheel driving via a directly connected pinion gear which drives a rack gear connected to a drawbar linking a crank member attached to the reflecting cradles such that motion of the wheel acts so as to drive all of the reflecting cradles an equal angle of rotation.

Preferably it has a (hail) comprising a surface of material fixed under and adjacent to but spaced away from the non=reflecting surfaces of the reflectors. The material is able to absorb impact energy from hail stones and other falling energy by means of plastic deformation. When the reflectors are invented, either manually or by an automatic drive (for example in response to a signal from an accelerometer or microphone, which may be mounted on the structure), the hail guard now faces upward and so any hail or other falling objects striking the reflector strikes the hail guard rather than the mirror surfaces.

Mounted to the receiver absorbing face, or constructed from it, is an array of photovoltaic cells for absorbing the reflected and concentrated sunlight. Suitable cells can be obtained from Q-Cells AG in Germany, for example their 125 mm×125 mm or 156 mm×156 mm polycrystalline cells of 15% +efficiency. Where crystalline or polycrystalline solar photovoltaic cells are used, copper conductors making electrical connections to the conductive tracking of the cells are braided to impart flexibility to the conductor to reduce to a low level mechanical stresses arising from the difference in thermal expansion of the semiconductor material of the photovoltaic cells and the copper of the conductor. The conductor is mechanically and electrically attached to the cell by means of a number of discrete and separate solder spots. The process for forming these is by fusing spots of solder on the cell tracks.

The braid is first pre-compressed to impart both axial as well as bending compliance to the braid. Then the braid is laid (optionally looped) over each linear array of solder spots, a free end is connected to an electrical conductor temporarily and in turn a carbon electrode, also connected to an electrical conductor, is pressed onto the braid over each solder spot and an electrical current is passed through the carbon electrode and the braid, heating up the electrode. For example an electrical power of approximately 100 W may be employed, by connecting a low voltage source (say 5 volts) between the free end of the braid and the carbon electrode, to supply approximately 20 amps. This may be generated from the secondary winding of a transformer, the number of turns being chosen to provide the desired voltage. The carbon electrode preferably comprises a metal (preferably copper) sheathed carbon rod (commercially available, for example, from Exactoscale Ltd, UK), the tip of which may be sharpened like a pencil so that it is the tip which heats up during the procedure.

Heat conducts from the electrode to the braid and then to solder spot on the cell, fusing the solder into the braid. After a short time of around 1-2s the current is switched off and pressure is continued on the carbon electrode until the solder has solidified. The process is repeated for all solder spots and all braid connections to the cell. This process allows the cell to be connected to a large cross sectional area of conductor to minimise the conductor resistance and permit the maximum power potential of cell to be realised.

The front grid of the cell is formed from fused silver-loaded conductive frit, which is the common process step for manufacturing crystalline and polycrystalline photovoltaic cells. For this invention, the spacing of lines of conductive frit is reduced to around 0.8 mm-1.4 mm from a more typical 3-5 mm spacing. This reduces the voltage drop in the cell material as current flows through it to the grid conductor and enables the cell to utilise the concentrated sunlight efficiently, shining with an intensity of around 7 kW per square metre on tile surface of the photovoltaic cell.

Preferably the receiver and cradles are much longer than the sum of the widths of the reflecting strips, as this minimises the proportion of reflected light not intercepted by the receiver.

Preferably at latitudes greater than 40 degrees relative to the plane of the pivoting axes of the cradles, the receiver is oriented east-west and the reflecting cradles are located on the same side of the receiver that its shadow falls at mid-day.

Preferably at latitudes less than 25 degrees relative to the plane of the pivoting axes of the cradles, the receiver is oriented north-south and the cradles are disposed either side of the receiver.

Preferably tubular passages are constructed from components that are attached to the thermally conducting elements with compression forces applied at regular intervals along each tubular passage so as to press the tubular passage firmly against a close fitting surface formed as part of the thermally conductive element, so as to maintain a large area of contact and small clearances between the thermally conductive element and the tubular passages.

Preferably the photovoltaic cells are fixed to the absorber face of the receiver with a thin (0.1-0.2 mm) of thermosetting elastomeric material so that the flexibility of this material prevents the differential thermal expansion of the cells material and the thermal conductor material from imparting significant mechanical stress to the cell.

Preferably all the cells are connected together in series. Bypass diodes are connected across groups of cells to minimise the power generated within a cells should one or more be in shadow. Preferably each cradle has 4 or 5 reflective strips mounted rigidly in each cradle, and four or five cradles reflect sunlight onto a single receiver,

Preferably each reflective laminate is flat across its width and along its length, so that it reflects the beam of direct sunlight with minimal convergence or divergence in any plane. Preferably the geometric normals of all the reflective strips on any one cradle meet at a single line (the cradle focal line).

Preferably all cradle focal lines lie on a cylindrical surface centred on tie principle axis of symmetry of the receiver absorber plane. The optimum radius of the location of these cradle focal lines depends on the orientation of the receiver axis and the angle of latitude relative to the plane of the cradle pivot axes. Typically the optimum radius of location of the cradle focal lines lies between 0-10% of the receiver height above the plane of tile cradle pivot axes.

A mirror actuator has a moving pivoting toothed element, rigidly fixed to a permanent magnet. This permanent magnet is magnetically connected to a ferromagnetic pole piece, which therefore is free to pivot. It can come into contact with and is mechanically constrained by either one of two ferromagnetic poles magnetically and mechanically rigidly connected together forming a stator. A coil or coils wound around the stator will determine the relative flux passing between each of the stator poles and therefore the direction of the force acting on the pivoting pole piece. Preferably the number of engaging teeth of each actuator is more than one

Once the pole piece has contacted a stator pole, it will preferentially remain attracted to it while the electrical current remains off. In this way pulses of current of alternate senses of sufficient magnitude actuate the pivoting pole piece and hence the engaging teeth in and out of engagement with the wheel.

Preferably the action of engaging another actuator and releasing the first actuator has the effect of rotating the wheel by one third of a tooth pitch. The direction of rotation can be altered by selecting the order of engagement of the actuators. Preferably a single actuation will drive the image of the sun less than or equal to 2-3% of the total width of the receiver. Preferably the rack is driven with at least two points of contact between the pinion and the rack in order to suppress backlash between the two components, by pressing the rack onto the pinion by one or more resiliently mounted roller or rollers. The actuator is controlled by sensors that detect the sunlight intensity and by sensors that detect the intensity of the image on the receiver either side of the absorber plane. The mirrors on the lower side of the cradles may be removed for a short length so that the cradles may be moved to a hail-safe position without the mirrors interfering with the frame or any driving links.

Preferably the mirrors are slightly distorted (bowed upwards) so that the optical focus does not have a break in the intensity along the focal line but rather the intensity is maintained at an approximately constant level. This is useful as it provides substantially even illumination along the receiver, improving the energy conversion of the system

We will also describe a solar collection system comprising: a framework with a multiplicity of bearings for supporting the pivoting cradles (four per receiver) as well as a line of posts for supporting the receiver at regular intervals, and a series of receiver units in a line, with the active absorbing area the width of a single photovoltaic cell.

Two pipes are fastened to the lengths of thermal conductive elements at regular intervals, each of the pair of pipes being connected to the adjacent lengths by push-in joints sealed with moulded elastomeric seals. To each thermal conductive element are adhered photovoltaic cells, each interconnected with copper braided conductors, each conductor soldered to the cell at a multiplicity of spots along the length and each braid soldered to an interconnecting bar to series connect all the cells. Each group of cells, six to a group, has a diode shunt to divert current in the event that the group is partially or wholly in shadow. The cells are encapsulated in ultraviolet resistant optically clear thermosetting elastomer and covered with a layer of toughened glass bonded to the elastomer.

Water is pumped through the pipes in the receiver and collected in a tank to operate other equipment that requires heat. Power is transferred to power consuming equipment. Four cradles reflect light onto the receiver, each cradle having a cradle focal line coincident with the principle axis of the receiver absorber when the normal of the plane of the centrelines of the reflective strips of all the cradles passes through the principle axis of the receiver absorber. This position of cradles corresponds to the position required to reflect sunlight onto the receiver with an angle of altitude of incoming direct radiation 50 degrees to the horizontal. The cradles are connected via crank arms to a drawbar, driven by a rack and an actuator, powered by photovoltaic energy. The actuator consists of three bistable actuators driving a 300-tooth gearwheel with an approximately sinusoidal gear profile. This gear directly drives an 18 tooth pinion. The rack is pressed against the pinion by two resiliently mounted rollers, pressing on the rear of the rack. The whole actuator is protected from the elements with a polymeric case.

A pin, extending from the actuator, is located in an arm which is pin jointed to the frame, allowing the actuator to be supported by the rack as it drives it.

An accelerometer microphone is connected to a central tube of a cradle. A photovoltaic array powers a signal processing unit and power supply. This is in turn connected to the permanent magnet locks that either fix the cradles onto the cranks or the frame. Torsion springs drive the cradles into the hail-safe position. An electric actuator turns the cradles back into the normally driven position after the hazard has stopped.

As the sun rises, sensors signal the actuator to move the cradles to move the reflected sunlight image onto the receiver. The cradles all move in response to the drawbar and crank motion. Once a sensor on the receiver detects a bright image on one side, it signals the actuator drive so as to move the image towards the other detector. Once the sensor signals are balanced the image is centred on the receiver. As the sun moves in altitude, small imbalances will be connected by occasional movements of die actuator.

Once fully illuminated, each cell generates a photovoltaic EMF and if the load is present, generates current. A typical commercial cell will generated up to 40 Amps of current at a voltage of 0.4 V. The heat absorbed will conduct through the cell and the thermally conductive element into the water flowing in the pipes.

Referring now to FIG. 1a, this diagram shows a perspective view of a system of distributed mirrors. Each mirror has a plurality if mirror elements or facets (105) where each facet comprises a laminated reflector (110). The facets operate in such a manner as to reflect direct sunlight onto line or strip focus (115) at which is located a receiver (160).

Referring to FIG. 1b the mirrors (105) may be made to change their tilt by means of an actuator (120) moving a drawbar (705) which defines the angle of tilt of each mirror (105). As may be seen in the figure, the facets of each mirror lie substantially in a plane although each facet is tilted with respect to it. The normal of this plane defines an axis which therefore rotates as the mirror rotates. The drawbar is connected via a rotating pin joint (145 of FIG. 7a) to a crank (700 of FIG. 7a) attached to each mirror assembly. The vectors from the centres of rotation of each mirror (150) to the pin joints (145) are substantially parallel and of equal length so that all mirrors rotate at substantially the same rate as the actuator moves the drawbar. This allows the sun to be focused on the receiver (160) as the solar disk apparently changes in altitude in the sky. The axis of the receiver is substantially parallel to the axes of rotation of the mirrors, the planes of the mirrors and the individual mirror facets.

Referring to FIG. 1c, the scale of width ‘B’ (e.g. 3.5 m) is selected so as to make the total solar collecting area per unit length of receiver (160) sufficient to achieve sufficient heat input into the receiver to be much greater than any heat losses arising from the receiver at its operating temperature (e.g. 90° for water). This then allows thermal energy to be captured with high efficiency. In order to minimise the proportion of light spilled off the ends of the receiver (160) when the direction of the solar rays have a non-zero component parallel to the receiver axis, the length ‘A’ (e.g. 12 m or 24 m) of the mirror system is much greater than the width ‘B’. The minors are supported by a mechanical mounting means (175) in which a bearing arrangement allows the tilting motion of each mirror. Gaps are left in the mirrors to allow large angles of tilt to occur unimpeded by the mechanical mounting means (175).

Referring to FIG. 1d, the system of distributed mirrors may be located over a roof (180) which may also contain glazing (185). Therefore the roof supports the mechanical mounting means (175). This glazing will then allow mostly diffuse light through to the under-storey with little glare, since most of the direct sunlight is reflected by the mirrors.

Referring to FIG. 2a, the diagram shows a sub-optimal system of reflectors configured for a tropical location. Direct sunlight strikes the mirrors in the reference direction (205), in this case vertically straight down. The mirrors and their facets are oriented by rotating the mirrors on their respective shafts 220 to produce a stripe focus (115) by focusing the reflected rays from the centre of each facet (210) to a focal line (200) by orientation of the normal vectors of each facet (215). In this sub-optimal example the plane of the mirrors lie substantially horizontal when the focusing direct light coming in the reference direction.

Referring to FIG. 2b, when the solar altitude has been lowered by 60 degrees (225) and the mirrors are tilted to focus the light at the receiver as before, the focus has become significantly softened. The spread of the mirror reflected rays ‘C’ is substantially greater than the width of each facet, significantly limiting the concentration of sunlight that can be achieved.

This is now contrasted with a preferred configuration, an example of which is shown in FIGS. 2c and 2d. In this example the geometry is suitable for a tropical location where the zenith is substantially normal to a plane defined by the axes of rotation of the mirrors.

Referring to FIG. 2c, the diagram shows a system of reflectors directed to direct sunlight from a reference direction which is vertically straight down. To fully optimise the performance each mirror has a ‘local focus’ located above the receiver on an optimal radius of location ‘R’ (e.g. 140 mm), which is typically a few percent, around 6% but it may be set for any value between 0% and 10% of the value of ‘D’, when the value of ‘E’ (e.g. 800 mm) is around 45% of the value of ‘D’ (e.g. 1750 mm). The plane passing through the centrelines of each facet on each mirror is oriented such that the normal to the planes passes through the stripe focus when focusing sunlight from the reference direction. The softening of the focus is small, around one third of the width of a single facet (and F is, for example, 170 mm).

Referring to FIG. 2d, when the sun is now 60 degrees lower in altitude in the sky and the mirrors have been tilted to reflect the light onto the same stripe as before, the amount of softening of the focus (H) is very small, demonstrating the very considerable improvement in concentration made possible by orienting the planes in which the facets of each mirror lies such that the facets are substantially equidistant from the receiver when the sunlight rays are in the reference direction. It is advantageous for this reference direction to be in tile mid-range of the variation of directions that the direct sunlight may strike the system of reflectors, for example to he the direction of the sun at local noon.

Referring to FIG. 3, the diagram shows a similar system of concentrators configured for a mid-latitude location rather than a tropical one. As before, when the direct sunlight is coming from the reference direction for this location (300) the planes in which the centreline of the facets lie are oriented normal to lines that pass from the focal stripe (115) to the centres of rotation of each minor (150).

Referring to FIG. 4a, the diagram shows the outer and centre facets of the mirror beneath the focal stripe shown in FIG. 3. The light is striking the mirror from the reference direction (300) and the focal stripe is a distance ‘I’ (which approximates to D in FIG. 2c) above the plane through the centrelines of the facets. The distance between the centrelines of the outer facets ‘G’ (e.g. approximately 0.5 m) is approximately 30% of the distance ‘I’. The facets are oriented so that the rays from the centrelines meet.

Referring to FIG. 4b, the solar disk is now much lower (405) in the sky and the tilted mirror is able to focus the direct sunlight from the centrelines of the facets to ‘J’, around 20% of the width of a facet, or around 1% of the height ‘I’ in FIG. 4a.

Referring to FIG. 4c, the sun is higher in the sky (410) and the tilted mirror is also able to focus the sunlight reflecting from the facet centrelines within ‘K’, 20% of the width of a facet.

In comparison, referring to FIG. 4d, a parabolic mirror with an offset vertex may be defined so as to focus the direction sunlight to focal line at the same height as in FIG. 4a.

Referring to FIG. 4e, direct sunlight from a low altitude solar disk (405) reflecting from the same parabolic mirror (415) causes the width of the focal line to spread, ‘L’, many times the width shown in FIG. 4b.

Referring to FIG. 4f, the direct sunlight from a high altitude solar disk (410) reflecting off the same parabolic mirror with a width ‘G’, equal to the distance between the outer facet centrelines shown in FIG. 4a, gives a focal width ‘M’ slightly greater than the focal width ‘K’ shown in FIG. 4c.

Where the aim is to generate a focal stripe of a controlled width and even illumination across the width—essential for focusing light onto photovoltaic cells—these FIGS. 4a-4f show that the use of individual facets provides for better focusing performance than can be expected from a parabolic mirror of the same dimensions as the facetted mirror.

Referring to FIG. 5a, the diagram depicts two reflective laminated facets 110 with a gap (165) where the bearing is positioned. Reflected rays of direct light from the ends of the facets are depicted as upward pointing straight up, implying that in this case the direct sunlight is moving in a plane normal to the plane of the facet. The gap in the rays will result in a ‘dark gap’ in the focal stripe.

Referring to FIG. 5b, this dark gap is made wider by the fact that there will be deflection of the structure between the mechanical mounting means supporting the facets due to the self weight of the structure and the laminated reflectors its supports. The curvature of the structure will result in a slope to the ends of the facets that will cause the direct light to be deflected outward, making the ‘dark gap’ appear longer.

Referring to FIG. 5c, the facets are mounted with a slight curvature to them so as to close up the gap. This compensating curvature, when unloaded, should more than compensate for the gap and the deflection so that, referring to FIG. 5d, when loaded with its self weight that light from the facets closes the dark gap and continuously illuminated stripe is formed at the receiver.

This detail to the design of the reflector is helpful for the efficient functioning of a receiver with photovoltaic cells as ideally all cells should be illuminated to the same extent since, to a first approximation, the current output of the string of cells is governed by the current produced by the least illuminated cell.

Referring to FIG. 6a, this shows the interior of an actuator which drives the drawbar that tilts the mirrors. In the diagram are shown three electromechanical actuators, each of which engage or disengage a pawl (605) about pivot (630).

Referring to FIG. 6b, an isometric view ‘A’ of one of the actuators shows the pawl (605), one of the set of three, driven by a ferromagnetic pole piece (610). Applying pulses of current of alternative sense to the coils (615) cause a pulse of magnetic field to move the ferromagnetic pole piece, rocking it back and forth around the pivot 630.

Referring to FIG. 6c, each pawl (605) engages with the gear wheel (600) so that as each pawl engages in turn, the gear is driven in steps of one third of a pitch of the teeth as the flanks of the teeth of the pawl slide against the flanks of the gear teeth, displacing the gear. The gear wheel (600) is connected rigidly to a pinion (635) which drives a rack (640) attached to the drawbar. The actuator pin 625 is restrained so that as the pinion is rotated tile rack is displaced.

Referring to FIG. 7a, this shows the actuator (120) and the drawbar (705), pin jointed to the equal length parallel cranks (700) that drive the mirrors (105). The mirrors are driven via magnetic catches (720) which can be released, allowing the mirrors to be inverted.

Referring to FIG. 7b, the mirrors (105) are now illustrated in the inverted position, so that shields (715), fixed to the mirror structure, are now located above the laminated reflectors to protect these from impact damage from falling or wind blown objects such as hail. When in this inverted position, the mirrors (105) are held by a second set of magnetic catches (725).

Referring to FIG. 8, this shows a sectional view through the receiver (160 of FIG. 1b). Heat transfer fluid (815) is pumped through tubular passages (815) pressed and fastened to close thermal contact with lengths of thermally conductive elements (830). Photovoltaic cells (820) are fixed to the absorber face of the thermally conductive elements (830) and in good thermal contact with them. Between the thermally conductive elements (830) and a transparent highly transmissive cover of toughened glass is an optically clear, thermosetting water repelling low modulus material so that the cells (820) are fully encapsulated in the clear elastomer (825). Optical sensors (800) are incorporated into the receiver assembly to sense the light levels either side of the stripe focus (115 of FIG. 1a). The sensors observe the light level through reflective tubular optical conduits (805).

Referring to FIG. 9, this is a circuit diagram of some of the photovoltaic cells (820) in a receiver (160, FIG. 1a). Each cell is connected electrically in parallel with a bypass, preferably Schottky diode (900). This allows the current flowing through an illuminated string of cells to bypass any photovoltaic cells which stay shaded, so that the voltage drop across the shaded cell is minimised. Further Schottky bypass diodes (905) are also connected across groups of cells (820) and bypass diodes (900), so that if a group of cells remain shaded, the voltage drop across the group is further reduced.

Referring to FIG. 10a, the front illuminated surface of the cell 820 has an arrangement of closely spaced narrow current collecting tracks (1000) printed onto the surface of the cell. Typically these tracks are made of silver-loaded ceramic frit. The wider tracks (1005) collect the current from the narrow tracks (1000).

Referring to FIG. 10b, over the wider tracks (1005 of FIG. 10a) on the front surface of the cell (820) are fused braids (1010) with a series of solder spots (1015). These lengths of braid (1010) lave been pre-compressed to ensure that the braid is flexible in both tension as well as compression.

Referring to FIG. 10c, which shows the rear surface of cell (820), a thicker gauge braid (1020) is fixed to conductive tracks with fused spots of solder (1015).

Referring to FIG. 10d, showing a side view of the cell (820), the braids on the front illuminated surface (1010) and the rear surface (1020) are looped between the solder spots (10150 fixing them to the conductive tracks. These loops assist in the flexibility of the braids, minimising forces arising from differential thermal expansion of the copper braid and the silicon or gallium arsenide cell materials.

Further aspects of the invention are defined in the following clauses:

1. A solar energy collection system comprising:

a solar energy receiver; and

a solar energy directing system to direct sunlight onto said solar energy receiver; wherein said solar energy directing system comprises a set of mirrors, each mirror having a moveable axis and comprising a plurality of facets, and

wherein the facets of each mirror are configured to direct incoming sunlight to focus substantially at said receiver when said mirror axes are directed towards said receiver.

2. A solar energy collection system as defined in clause 1 wherein the facets of a said mirror are disposed about said axis at substantially equal distances from said receiver.

3. A solar energy collection system as defined in clause 1 or 2 wherein the facets of a said mirror are disposed substantially in a plane, and wherein the axis of said mirror is substantially perpendicular to said plane.

4. A solar energy collection system as defined in any preceding clause wherein each said mirror axis is rotatable about an axis of rotation, the axes of rotation of said mirrors being substantially parallel and defining a longitudinal direction, said mirrors and receiver extending in said longitudinal direction.

5. A solar energy collection system as defined in clause 4 wherein said mirrors have substantially no longitudinal focussing power.

6. A solar energy collection system as defined in clause 5 or 6 further comprising a mirror drive to rotate said mirrors about their respective axes of rotation and configured such that during rotation all the mirrors rotate by substantially the same angle.

7. A solar energy collection system comprising:

a solar energy receiver; and

a solar energy directing system to direct sunlight onto said solar energy receiver; wherein

said solar energy directing system comprises a set of mirror assemblies, each mirror assembly having a moveable axis and comprising a plurality of mirror elements, and wherein the elements of each mirror are configured such that when each mirror axis is directed substantially towards said receiver there is a reference direction from which incoming substantially parallel light is substantially focussed onto said receiver.

8. A solar energy directing system comprising:

a plurality of mirror assemblies, each having mounted thereon a plurality of mirror elements, said mirror elements of a mirror assembly having a fixed mutual position and orientation; and

a plurality of mirror assembly supports each configured to provide a respective mirror assembly with an axis of rotation about a longitudinal direction, said axes of rotation being substantially mutually parallel; and wherein said mirror assemblies are configured to bring incoming parallel light to a stripe focus substantially parallel to said longitudinal direction.

9. A solar energy directing system as defined in clause 8 further comprising a mirror drive to rotate each said mirror assembly at substantially the same rate.

10. A solar energy directing system as defined in clause 8 or 9 wherein each said mirror element extends longitudinally substantially parallel to said axes of rotation.

11. A solar energy directing system as defined in clause 10 wherein said mirror elements are mounted on a said mirror assembly to define a plane substantially perpendicular to a direction in which a said mirror assembly focuses light.

12. A solar energy directing system comprising:

a plurality of mirror assemblies, each having mounted thereon a plurality of mirror elements, said mirror elements of a mirror assembly having a fixed mutual position and orientation; and

a plurality of mirror assembly supports each configured to provide a respective mirror assembly with an axis of rotation about a longitudinal direction, said axes of rotation being substantially mutually parallel; and

wherein said mirror assemblies are configured for rotation in synchrony each at substantially the same rate.

13. A solar energy collection system comprising:

a solar energy receiver; and

a solar energy directing system to direct sunlight onto said solar energy receiver; wherein

said solar energy directing system comprises a set of Fresnel mirrors, each comprising a plurality of mirror facets, each positioned at an angle with respect to a reference direction such that incoming light from said reference direction is reflected towards said solar energy receiver; and wherein at least some of said Fresnel mirrors are configured as off-axis mirrors such that incoming parallel off-axis rays are focussed on-axis.

14. A solar energy collection system as defined in clause 13 wherein each said mirror facet has a substantially planar reflecting surface.

15. A solar energy collection system as defined in clause 14 wherein each said mirror facet is positioned such that incoming light from said reference direction is reflected towards said solar energy receiver.

16. A solar energy collection system as defined in clause 13 or 14 wherein a said mirror facet has a dimension such that said reflected incoming light extends substantially uniformly over substantially no more than an energy collecting portion of said solar energy receiver.

17. A solar energy collection system as defined in clause 13, 14, 15 or 16 wherein said mirrors are move able.

18. A solar energy collection system as defined in clause 17 wherein said mirrors are rotatable about an axis, and further comprising means to synchronise said rotation such that when said mirrors rotate each rotates by substantially the same angle.

19. A solar energy collection system as defined in any one of clauses 13 to 18 wherein said set of mirrors comprises between two and ten mirrors, preferably between four and eight mirrors.

20. A solar energy collection system as defined in any one of clauses 13 to 19 wherein each said mirror extends longitudinally such that said sunlight is directed into a stripe at said solar energy receiver, and wherein said receiver extends longitudinally along a direction of said stripe.

21. A solar energy collection system as defined in clause 20 wherein said mirrors are rotatable about said longitudinal direction to follow an attitudinal motion of the sun.

22. A solar energy collection system as defined in clause 21 wherein a said mirror is rotatable to substantially invert the mirror.

23. A solar energy collection system as defined in any one of clause 13 to 22 wherein a said mirror is moveable to face generally downwards to protect a reflecting surface of the mirror.

24. A solar energy collection system as defined in clause 22 or 23 wherein a said mirror has a rear shield for weather protection.

25. A solar energy collection system as defined in any one of clause 13 to 24 wherein said mirrors are positioned substantially in a common plane.

26. A solar energy collection system as defined in any one of clauses 13 to 25 for installation at an installation latitude, and wherein said reference direction is defined by said installation latitude.

27. A solar energy collection system as defined in any preceding clause wherein said solar energy receiver points downwards.

28. A solar energy collection system as defined in any preceding clause wherein said solar energy receiver is configured for supplying for use both heat and electrical power.

29. A solar energy collection system comprising:

a solar energy receiver configured for supplying for use both heat and electrical power; and a solar energy directing system to direct sunlight onto said solar energy receiver; wherein

said solar energy directing system comprises a set of mirrors, each positioned at an angle with respect to a predetermined reference direction such that incoming light from said reference direction is reflected towards said solar energy receiver;

wherein each said mirror extends longitudinally such that said sunlight is directed into a stripe at said solar energy receiver, and wherein said receiver extends longitudinally along a direction of said stripe;

said set of mirrors taken as a whole providing a reflecting surface with an aspect ratio of greater than 5:1.

30. A solar energy collection system as defined in clause 29 wherein said aspect ratio is greater than 10:1.

31. A solar energy collection system as defined in clause 29 or 30 wherein said receiver includes a photovoltaic device and conductors for a heat transfer fluid, and wherein said energy collection system is configured such that in operation said heat transfer fluid is heated to close to a boiling point of the fluid as determined for the fluid under atmospheric pressure.

32. A solar energy collection system comprising:

a solar energy receiver configured for supplying for use both heat and electrical power; and

a solar energy directing system to direct sunlight onto said solar energy receiver; and wherein

said receiver includes a photovoltaic device and conductors for a heat transfer fluid, and wherein said energy collection system is configured such that in operation said heat transfer fluid is heated to close to a boiling point of the fluid as determined for the fluid under atmospheric pressure.

33. A building having a solar energy collection system as defined in any preceding clause on a roof of the building such that at least a portion of the building is illuminated by indirect sunlight passing between mirrors of said set of mirrors.

34. A building having a solar energy collection system including a solar energy receiver configured for supplying for use both heat and electrical power; wherein the system is mounted on a roof of the building such that at least a portion of the building is illuminated by indirect sunlight passing between mirrors of said set of mirrors.

35. A photovoltaic device comprising a light receiving surface and first and second electrodes for delivering electrical power from the device, the device having at least one high current electrical contact, at least one of said first and second electrodes comprising a plurality of electrically conductive tracks; and wherein said high current electrical contact comprises at least one metallic conductor crossing said plurality of tracks and attached to each track at a respective crossing point, said metallic conductor being configured to permit an increase in separation between said crossing points.

36. A photovoltaic device as defined in clause 35 wherein said metallic conductor comprises pre- compressed braid.

37. A photovoltaic device as defined in clause 35 or 36 wherein said metallic conductor has a length between said crossing points greater than a distance between said crossing points.

38. A photovoltaic device as defined in clause 37 wherein said metallic conductor is looped between said crossing points.

39. A photovoltaic device in any one of clauses 35 to 38 wherein said conductor is soldered to each said track.

40. A photovoltaic device in any one of clauses 35 to 39 wherein said tracks overlie a surface of said device.

41. A photovoltaic device in any one of clauses 35 to 40 wherein said high current contact comprises a plurality of said metallic conductors

42. A photovoltaic device in any one of clauses 35 to 41 wherein both said first and second electrodes comprise a plurality of said conductive tracks, and wherein two of said high current contacts are provided, one for each of said electrodes.

43. A photovoltaic device in any one of clauses 35 to 42 wherein said conductive tracks have a spacing of less than 2 mm, more preferably less than 1.5 mm or 1 mm.

44. A photovoltaic device in any one of clauses 35 to 43 wherein said conductive tracks comprise silver and wherein said conductor comprises copper.

45. A solar energy collection system including the photovoltaic device of any one of clauses 35 to 44.

46. A solar energy collection system as defined in clause 45 including means to concentrate collected solar energy onto said device.

47. A solar energy collection system as defined in clause 46 further comprising cooling means for said device.

48. A solar energy collection system including a photovoltaic device, means to concentrate collected solar energy onto said device, and cooling means for said device, said photovoltaic device comprising a light receiving surface and first second electrodes for delivering electrical power from the device, at least one of said first and second electrodes comprising a plurality of electrically conductive tracks, and wherein said tracks overlie a surface of said device.

49. A solar energy collection system as defined in clause 47 or 48 configured to provide combined heat and power.

50. A photovoltaic device comprising a light receiving surface and first and second electrodes for delivering electrical power from the device, at least one of said first and second electrodes comprising a plurality of electrically conductive tracks and wherein said conductive tracks have a spacing of less than 2 mm, more preferably less than 1.5 mm or 1 mm.

51. A process for attaching an electrical contact to a photovoltaic device, the photovoltaic device comprising a light receiving surface and first and second electrodes for delivering electrical power from the device, at least one of said first and second electrodes comprising a plurality of electrically conductive tracks, the method comprising:

applying solder to said plurality of tracks at points where said contact is to be attached;

placing said electrical contact adjacent one or more of said attachment points; and

heating said one or more attachment points to melt said solder and attach said contact at said attachment points.

53. A photovoltaic device as defined in clause 51 or 52 wherein said contact comprises a conductor configured to permit an increase in separation between said attachment points due to thermal expansion in use.

54. A photovoltaic device as defined in clause 51, 52 or 53 wherein said contact comprises a metallic braid.

55. A photovoltaic device with at least one electrode comprising a plurality of electrically conductive tracks, for use in a solar concentrator with a pre-determined concentration factor, in which the separation of the tracks is substantially equal to or less than a value determined according to a square root of the concentration factor.

No doubt many other effective alternatives will occur to the skilled person. It will be understood that the invention is not limited to the described embodiments and encompasses modifications apparent to those skilled in the art lying within the spirit and scope of the claims appended hereto.

1-55. (canceled)

56. A solar energy collection system comprising:
a solar energy receiver; and
a solar energy directing system to direct sunlight onto said solar energy receiver; wherein
said solar energy directing system comprises a set of mirrors, each mirror having a moveable axis and comprising a plurality of facets, and
wherein the facets of each mirror are configured to direct incoming sunlight to focus substantially at said receiver when said mirror axes are directed towards said receiver.

57. A solar energy collection system as claimed in claim 56 wherein the facets of a said mirror are disposed about said axis at substantially equal distances from said receiver.

58. A solar energy collection system as claimed in claim 56 wherein the facets of a said mirror are disposed substantially in a plane, and wherein the axis of said mirror is substantially perpendicular to said plane.

59. A solar energy collection system as claimed in claim 56 wherein each said mirror axis is rotatable about an axis of rotation, the axes of rotation of said mirrors being substantially parallel and defining a longitudinal direction, said mirrors and receiver extending in said longitudinal direction.

60. A solar energy collection system as claimed in claim 59 wherein said mirrors have substantially no longitudinal focussing power.

61. A solar energy collection system as claimed in claim 60 further comprising a mirror drive to rotate said mirrors about their respective axes of rotation and configured such that during rotation all the mirrors rotate by substantially the same angle.

62. A solar energy collection system comprising:
a solar energy receiver; and
a solar energy directing system to direct sunlight onto said solar energy receiver; wherein
said solar energy directing system comprises a set of mirror assemblies, each mirror assembly having a moveable axis and comprising a plurality of mirror elements, and wherein the elements of each mirror are configured such that when each mirror axis is directed substantially towards said receiver there is a reference direction from which incoming substantially parallel light is substantially focussed onto said receiver.

63. A solar energy directing system comprising:
a plurality of mirror assemblies, each having mounted thereon a plurality of mirror elements, said mirror elements of a mirror assembly having a fixed mutual position and orientation; and
a plurality of mirror assembly supports each configured to provide a respective mirror assembly with an axis of rotation about a longitudinal direction, said axes of rotation being substantially mutually parallel; and
wherein said mirror assemblies are configured to bring incoming parallel light to a stripe focus substantially parallel to said longitudinal direction.

64. A solar energy directing system as claimed in claim 63 further comprising a mirror drive to rotate each said mirror assembly at substantially the same rate.

65. A solar energy directing system as claimed in claim 63 wherein each said mirror element extends longitudinally substantially parallel to said axes of rotation.

66. A solar energy directing system as claimed in claim 65 wherein said mirror elements are mounted on a said mirror assembly to define a plane substantially perpendicular to a direction in which a said mirror assembly focuses light.

67. A solar energy directing system comprising:
a plurality of mirror assemblies, each having mounted thereon a plurality of mirror elements, said mirror elements of a mirror assembly having a fixed mutual position and orientation; and
a plurality of mirror assembly supports each configured to provide a respective mirror assembly with an axis of rotation about a longitudinal direction, said axes of rotation being substantially mutually parallel; and
wherein said mirror assemblies are configured for rotation in synchrony each at substantially the same rate.

68. A solar energy collection system comprising:
a solar energy receiver; and
a solar energy directing system to direct sunlight onto said solar energy receiver; wherein
said solar energy directing system comprises a set of Fresnel mirrors, each comprising a plurality of mirror facets, each positioned at an angle with respect to a reference direction such that incoming light from said reference direction is reflected towards said solar energy receiver; and wherein at least some of said Fresnel mirrors are configured as off-axis mirrors such that incoming parallel off-axis rays are focussed on-axis.

69. A solar energy collection system as claimed in claim 68 wherein each said mirror facet has a substantially planar reflecting surface.

70. A solar energy collection system as claimed in claim 69 wherein each said mirror facet is positioned such that incoming light from said reference direction is reflected towards said solar energy receiver.

71. A solar energy collection system as claimed in claim 68 wherein a said mirror facet has a dimension such that said reflected incoming light extends substantially uniformly over substantially no more than an energy collecting portion of said solar energy receiver.

72. A solar energy collection system as claimed in claim 68 wherein said mirrors are moveable.

73. A solar energy collection system as claimed in claim 72 wherein said mirrors are rotatable about an axis, and further comprising means to synchronise said rotation such that when said mirrors rotate each rotates by substantially the same angle.

74. A solar energy collection system as claimed in claim 68 wherein said set of mirrors comprises between two and ten mirrors, preferably between four and eight mirrors.

75. A solar energy collection system as claimed in claim 68 wherein each said mirror extends longitudinally such that said sunlight is directed into a stripe at said solar energy receiver, and wherein said receiver extends longitudinally along a direction of said stripe.

76. A solar energy collection system as claimed in claim 75 wherein said mirrors are rotatable about said longitudinal direction to follow an altitudinal motion of the sun.

77. A solar energy collection system as claimed in claim 76 wherein a said mirror is rotatable to substantially invert the mirror.

78. A solar energy collection system as claimed in claim 68 wherein a said mirror is moveable to face generally downwards to protect a reflecting surface of the mirror.

79. A solar energy collection system as claimed in claim 77 wherein a said mirror has a rear shield for weather protection.

80. A solar energy collection system as claimed in claim 68 wherein said mirrors are positioned substantially in a common plane.

81. A solar energy collection system as claimed in claim 68 for installation at an installation latitude, and wherein said reference direction is defined by said installation latitude.

82. A solar energy collection system as claimed in claim 56 wherein said solar energy receiver points downwards.

83. A solar energy collection system as claimed in claim 56 wherein said solar energy receiver is configured for supplying for use both heat and electrical power.

84. A solar energy collection system comprising:
a solar energy receiver configured for supplying for use both heat and electrical power; and
a solar energy directing system to direct sunlight onto said solar energy receiver; wherein
said solar energy directing system comprises a set of mirrors, each positioned at an angle with respect to a predetermined reference direction such that incoming light from said reference direction is reflected towards said solar energy receiver;
wherein each said mirror extends longitudinally such that said sunlight is directed into a stripe at said solar energy receiver, and wherein said receiver extends longitudinally along a direction of said stripe;
said set of mirrors taken as a whole providing a reflecting surface with an aspect ratio of greater than 5:1.

85. A solar energy collection system as claimed in claim 84 wherein said aspect ratio is greater than 10:1.

86. A solar energy collection system as claimed in claim 84 wherein said receiver includes a photovoltaic device and conductors for a heat transfer fluid, and wherein said energy collection system is configured such that in operation said heat transfer fluid is heated to close to a boiling point of the fluid as determined for the fluid under atmospheric pressure.

87. A solar energy collection system comprising:
a solar energy receiver configured for supplying for use both heat and electrical power; and
a solar energy directing system to direct sunlight onto said solar energy receiver; and wherein
said receiver includes a photovoltaic device and conductors for a heat transfer fluid, and wherein said energy collection system is configured such that in operation said heat transfer fluid is heated to close to a boiling point of the fluid as determined for the fluid under atmospheric pressure.

88. A building having a solar energy collection system as claimed in claim 56 on a roof of the building such that at least a portion of the building is illuminated by indirect sunlight passing between mirrors of said set of mirrors.

89. A building having a solar energy collection system including a solar energy receiver configured for supplying for use both heat and electrical power; wherein the system is mounted on a roof of the building such that at least a portion of the building is illuminated by indirect sunlight passing between mirrors of said set of mirrors.

90. A photovoltaic device comprising a light receiving surface and first and second electrodes for delivering electrical power from the device, the device having at least one high current electrical contact, at least one of said first and second electrodes comprising a plurality of electrically conductive tracks; and wherein
said high current electrical contact comprises at least one metallic conductor crossing said plurality of tracks and attached to each track at a respective crossing point, said metallic conductor being configured to permit an increase in separation between said crossing points.

91. A photovoltaic device as claimed in claim 90 wherein said metallic conductor comprises pre-compressed braid.

92. A photovoltaic device as claimed in claim 90 wherein said metallic conductor has a length between said crossing points greater than a distance between said crossing points.

93. A photovoltaic device as claimed in claim 92 wherein said metallic conductor is looped between said crossing points.

94. A photovoltaic device as claimed in claim 90 wherein said conductor is soldered to each said track.

95. A photovoltaic device as claimed in claim 90 wherein said tracks overlie a surface of said device.

96. A photovoltaic device as claimed in claim 90 wherein said high current contact comprises a plurality of said metallic conductors

97. A photovoltaic device as claimed in claim 90 wherein both said first and second electrodes comprise a plurality of said conductive tracks, and wherein two of said high current contacts are provided, one for each of said electrodes.

98. A photovoltaic device as claimed in claim 90 wherein said conductive tracks have a spacing of less than 2 mm, more preferably less than 1.5 mm or 1 mm.

99. A photovoltaic device as claimed in claim 90 wherein said conductive tracks comprise silver and wherein said conductor comprises copper.

100. A solar energy collection system including the photovoltaic device of claim 90.

101. A solar energy collection system as claimed in claim 100 including means to concentrate collected solar energy onto said device.

102. A solar energy collection system as claimed in claim 101 further comprising cooling means for said device.

103. A solar energy collection system including a photovoltaic device, means to concentrate collected solar energy onto said device, and cooling means for said device, said photovoltaic device comprising a light receiving surface and first second electrodes for delivering electrical power from the device, at least one of said first and second electrodes comprising a plurality of electrically conductive tracks, and wherein said tracks overlie a surface of said device.

104. A solar energy collection system as claimed in claim 102 configured to provide combined heat and power.

105. A photovoltaic device comprising a light receiving surface and first and second electrodes for delivering electrical power from the device, at least one of said first and second electrodes comprising a plurality of electrically conductive tracks and wherein said conductive tracks have a spacing of less than 2 mm, more preferably less than 1.5 mm or 1 mm.

106. A process for attaching an electrical contact to a photovoltaic device, the photovoltaic device comprising a light receiving surface and first and second electrodes for delivering electrical power from the device, at least one of said first and second electrodes comprising a plurality of electrically conductive tracks, the method comprising:
applying solder to said plurality of tracks at points where said contact is to be attached;
placing said electrical contact adjacent one or more of said attachment points; and
heating said one or more attachment points to melt said solder and attach said contact at said attachment points.

107. A process as claimed in claim 106 wherein said heating comprises passing a current through said electrical contact using one or more electrodes positioned at said one or more attachment points, a said electrode having a greater electrical resistance than said conductors.

108. A photovoltaic device as claimed in claim 106 wherein said contact comprises a conductor configured to permit an increase in separation between said attachment points due to thermal expansion in use.

109. A photovoltaic device as claimed in claim 106 wherein said contact comprises a metallic braid.

110. A photovoltaic device with at least one electrode comprising a plurality of electrically conductive tracks, for use in a solar concentrator with a pre-determined concentration factor, in which the separation of the tracks is substantially equal to or less than a value determined according to a square root of the concentration factor.
